(19) United States
(12) Patent Application Publication
(10) Pub. No.: US 2006/0233004 A1
(43) Pub. Date: Oct. 19, 2006

(54) Car power source apparatus

(76) Inventors: Kimihiko Furukawa, Kakogawa-city (JP); Masahiko Hashimoto, Kasai-city (JP)

Correspondence Address: WENDEROTH, LIND & PONACK, L.L.P., 2033 K STREET N. W., SUITE 800, WASHINGTON, DC, 20006-1021, US

(21) Appl. No.: 11/373,101

(22) Filed: Mar. 13, 2006

(30) Foreign Application Priority Data
Mar. 30, 2005 (JP) 99312/2005

(51) Int. Cl. G11C 19/08

(52) U.S. Cl. 365/1

(57) ABSTRACT

The car power source apparatus is provided with a battery having a plurality of battery modules connected in series on positive and negative sides of a reference node, and a voltage detection circuit to detect battery module voltage with respect to the battery reference node. The battery reference node of the power source apparatus is connected to the voltage detection circuit via a reference connection line, and battery voltage detection nodes are connected to the voltage detection circuit via voltage detection lines. The voltage detection circuit detects detection node voltages to determine battery module voltages. The voltage detection circuit has detection switches connected in voltage detection lines, detection node voltages are detected with detection switches in the OFF state, and reference connection line open circuit is detected from those detected voltages.

### BACKGROUND OF THE INVENTION

1. Field of the Invention

This invention relates to a power source apparatus for powering the driving motor of an electric vehicle, such as a hybrid car or electric automobile, and in particular, relates to a car power source apparatus having a simple circuit structure that can detect open circuit of a reference connection line, which determines battery module voltage.

2. Description of Related Art

To increase power source apparatus output to drive an electric vehicle, it is necessary to increase battery voltage. This is because power output is proportional to the product of battery voltage and current. For example, power source apparatus batteries for hybrid cars and electric automobiles are extremely high voltage at 200V or more. In a high voltage battery, a plurality of rechargeable batteries are connected in series to form battery modules, and those battery modules are again connected in series to increase output voltage.

In this type of battery comprising a large number of battery modules connected in series, it is important to charge and discharge the battery while preventing over-charge and over-discharge of each battery module. This is because over-charge and over-discharge degrade a battery's electrical performance and shorten its lifetime. A car power source apparatus has been developed to prevent battery module over-charge and over-discharge by detecting battery module voltage and controlling battery charge and discharge (refer to Japanese Patent Application Disclosure 2002-199510).

### SUMMARY OF THE INVENTION

The power source apparatus cited in this reference disclosure detects the voltage of each battery module via a difference amplifier. In this power source apparatus, the voltage between the input terminal pair of each difference amplifier is roughly constant, but the voltage between input terminals and ground increases with each battery module. This is because the voltage with respect to ground of each series connected battery module gradually increases as the number of battery modules increases, and each difference amplifier detects that voltage. As a result, circuit design of the difference amplifiers becomes complex, or it becomes necessary to use high power supply voltage difference amplifiers.

As shown in FIG. 1, this drawback can be eliminated with a voltage detection circuit 23 which detects the voltage of each connection node with respect to a midpoint reference node 28 near the midpoint potential of all the battery modules 22. The voltage detection circuit 23 of this figure detects battery module 22 voltage from the difference between voltages at battery module 22 connection nodes. Since this voltage detection circuit 23 detects voltages of battery module 22 connection nodes with respect to the midpoint reference node 28, all detected voltages are referenced with respect to the midpoint reference. Consequently, as shown in the figure, battery module 22 connection nodes are switched via a multiplexer 24 to allow detection of connection node voltages.

However, this voltage detection circuit 23 detects all voltages as voltage with respect to the midpoint reference node 28. Therefore, if the reference connection line 29, which connects the midpoint reference node 28 to the voltage detection circuit 23, becomes open circuited, no battery module 22 voltage can be accurately detected. The reference connection line 29 connects the midpoint reference node 28 of the battery 21 to the voltage detection circuit 23 via conductors such as a connecting cord and connectors, or a connecting cord and terminals. Connectors and terminals electrically connect by mutually applied pressure on opposing metal surfaces. Change in metal surface properties over time cannot be neglected. Change in metal surface properties can cause contact resistance. In particular, since cars are used in external environments of extreme temperature, humidity, and dust, etc., changes in connector and terminal properties cannot be ignored. Reference connection line connector or terminal contact failure causes high or variable contact resistance resulting in an unstable, shifting midpoint reference voltage. Further, if the reference connection line becomes open circuited, voltage at the midpoint reference node cannot be detected. If battery module voltage cannot be accurately detected in a car power source apparatus, severe battery degradation can result from over-charge or over-discharge, or even though the battery can be charged and discharged, charge and discharge are abnormally limited or halted, and the car cannot be driven normally by the battery.

To eliminate this drawback, the present applicant developed a power source apparatus provided with a circuit to detect reference connection line open circuit (Japanese Patent Application 2004-187843). As shown in FIG. 2, this power source apparatus is provided with a detection circuit 30 to force current through reference connection lines 39 and detect any open circuit. The detection circuit 30 is a series connection of on-off switches 35, current limiting resistor 36, and photo-coupler 37. To more reliably detect reference connection line 39 open circuit, the detection circuit 30 has two parallel series connected circuits of on-off switches 35, current limiting resistor 36, and photo-coupler 37 allowing detection of the reference connection line 39 even when one of the series connected circuits has failed. In this detection circuit 30, when an on-off switch 35 is turned on, a prescribed current flows through the reference connection line 39. The current signal is input to a decision circuit 40 via the photo-coupler 37. In this figure, 31 is the battery, 32 are battery modules, 33 is a voltage detection circuit, 34 is a multiplexer, and 38 is the midpoint reference node.

This detection circuit can reliably detect reference connection line open circuit. However, it has the drawback of high manufacturing cost because it is necessary to a provide special purpose detection circuit. In particular, the detection circuit operates only during the extremely short periods that the ignition switch is on and its use is limited only to detecting open circuit of a reference connection line. Consequently, a detection circuit with a simple circuit structure is sought to reduce manufacturing cost.

In addition, use of this detection circuit is limited in a power source apparatus with short circuit current limiting resistors in the voltage detection lines that connect battery module connection nodes to the voltage detection circuit. This is because short circuit current limiting resistors reduce current in the photo-coupler and prevent the photo-coupler from turning on. This drawback can be eliminated by bypassing the short circuit current limiting resistors with special purpose connecting lines. However, installation of special purpose lines is complex and introduces other drawbacks such as inability to limit current for short circuit in a special purpose line.

The present invention was developed to further resolve the drawbacks described above. Thus it is a primary object of the present invention to provide a car power source apparatus that can detect reference connection line open circuit via a simple circuit structure, can determine whether or not the voltage detection function is negatively affected, and can charge and discharge battery modules while protecting them.

To realize the object described above, the car power source apparatus of the present invention has the following configuration. The car power source apparatus is provided with a battery 1 having a plurality of series connected battery modules 2 on the positive and negative sides of a reference node 8, and a voltage detection circuit 3 to detect the voltage of one or a plurality of battery modules 2 with respect to the reference node 8. In the car power source apparatus, a reference node 8 of the battery 1 is connected to the voltage detection circuit 3 via a reference connection line 9, voltage detection nodes 7 of the battery 1 are connected to the voltage detection circuit 3 via voltage detection lines 10, and voltage detection node 7 voltages are detected by the voltage detection circuit 3 to determine battery module 2 voltages. The voltage detection circuit 3 has detection switches 12 connected in the voltage detection lines 10, voltage detection node 7 voltages are detected with the detection switches 12 in the OFF state, and reference connection line 9 open circuit is detected from those node voltages.

The car power source apparatus described above has the characteristic that it can detect a reference connection line open circuit with a simple circuit structure, it can determine whether or not a problem has developed that will negatively impact the voltage detection function, and it can charge and discharge battery modules while protecting them. This is because the car power source apparatus has a battery reference node connected to the voltage detection circuit via a reference connection line, it has battery voltage detection nodes connected to the voltage detection circuit via voltage detection lines, and it detects node voltages with the voltage detection circuit to determine battery module voltages. Further, the voltage detection circuit has detection switches in the voltage detection lines, voltage detection node voltages are detected with the detection switches in the OFF state, and reference connection line open circuit is detected from those node voltages. In a power source apparatus of this configuration with detection switches in the OFF state, current will flow through different circuits, and detected node voltages will vary depending on whether the reference connection line is open circuited or not. Therefore, reference connection line open circuit can be determined by detecting and discriminating those node voltage variations. In particular, the power source apparatus described above is not provided with a special purpose detection circuit as in prior art. Consequently, simple circuit structure allows manufacturing cost reduction.

In the car power source apparatus of the present invention, voltage detection lines 10 are provided for each battery module 2 connection node, and the voltage of each battery module 2 can be detected by the voltage detection circuit 3.

In the car power source apparatus of the present invention, the voltage detection circuit 3 is provided with a resistor voltage divider circuit 11, and voltage input from a voltage detection line 10 can be detected after voltage division by the voltage divider circuit 11.

In the car power source apparatus of the present invention, detection switches 12 connected in all voltage detection lines 10 can serve a dual purpose as current cut-off switches to cut-off discharge current from the battery 1. In such a power source apparatus, reference connection line 9 open circuit can be detected by turning some of the detection switches 12 OFF.

Finally, in the car power source apparatus of the present invention, current limiting resistors can be connected in all the voltage detection lines 10.

The above and further objects and features of the invention will more fully be apparent from the following detailed description with accompanying drawings.

### BRIEF DESCRIPTION OF THE DRAWINGS

FIG. 1 is a circuit diagram showing the voltage detection circuit of a prior art power source apparatus.

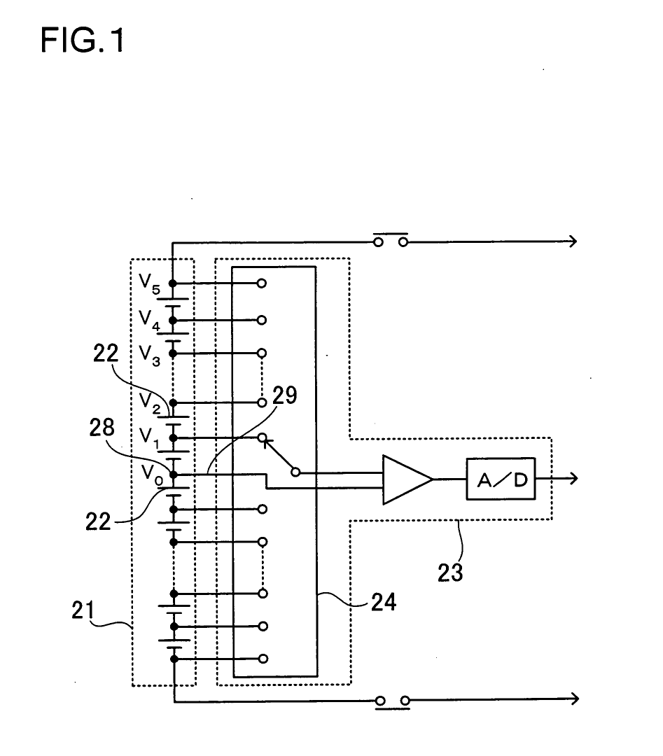

FIG. 2 is a schematic structural diagram of a car power source apparatus previously developed by the present applicant.

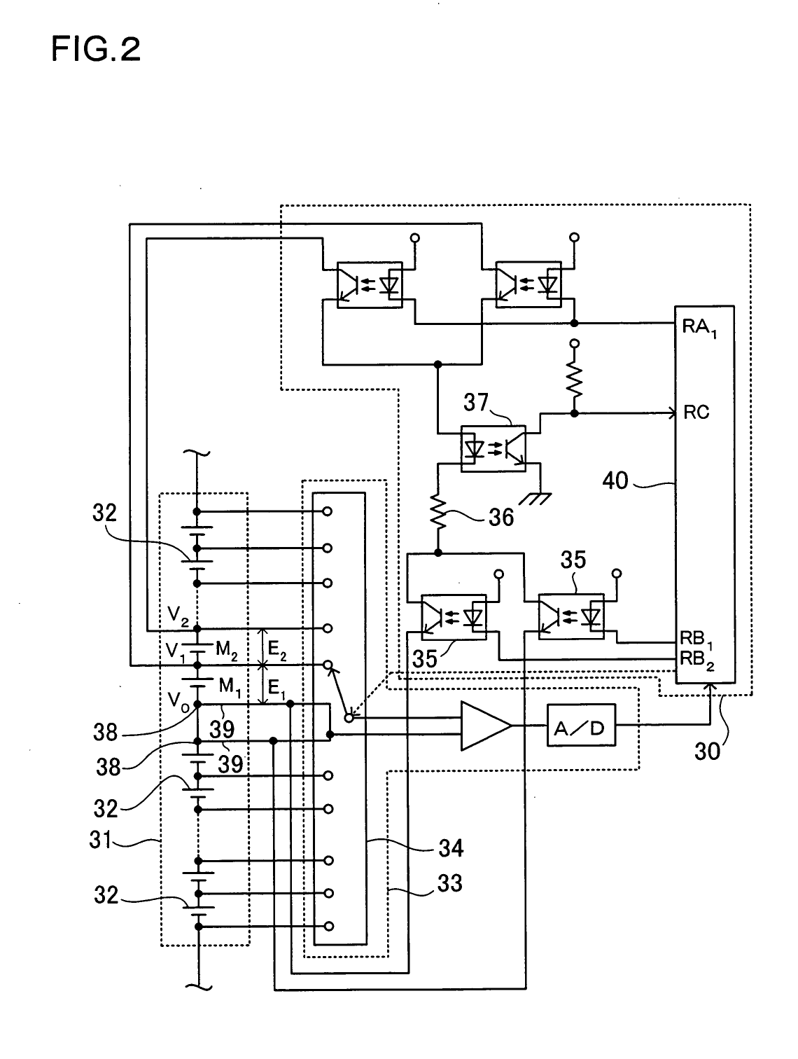

FIG. 3 is a schematic structural diagram of a car power source apparatus for the first embodiment of the present invention.

FIG. 4 is a schematic structural diagram of a car power source apparatus for the second embodiment of the present invention.

FIG. 5 is a schematic structural diagram of a car power source apparatus for the third embodiment of the present invention.

FIG. 6 is a schematic structural diagram of a car power source apparatus of another embodiment of the present invention.

FIG. 7 is a diagram demonstrating operating principles of the power source apparatus shown in FIG. 3.

FIG. 8 is a diagram demonstrating operating principles of the power source apparatus shown in FIG. 3.

FIG. 9 is a flow-chart for detecting reference connection line open circuit with the power source apparatus shown in FIG. 3.

### DETAILED DESCRIPTION OF THE PREFERRED EMBODIMENTS

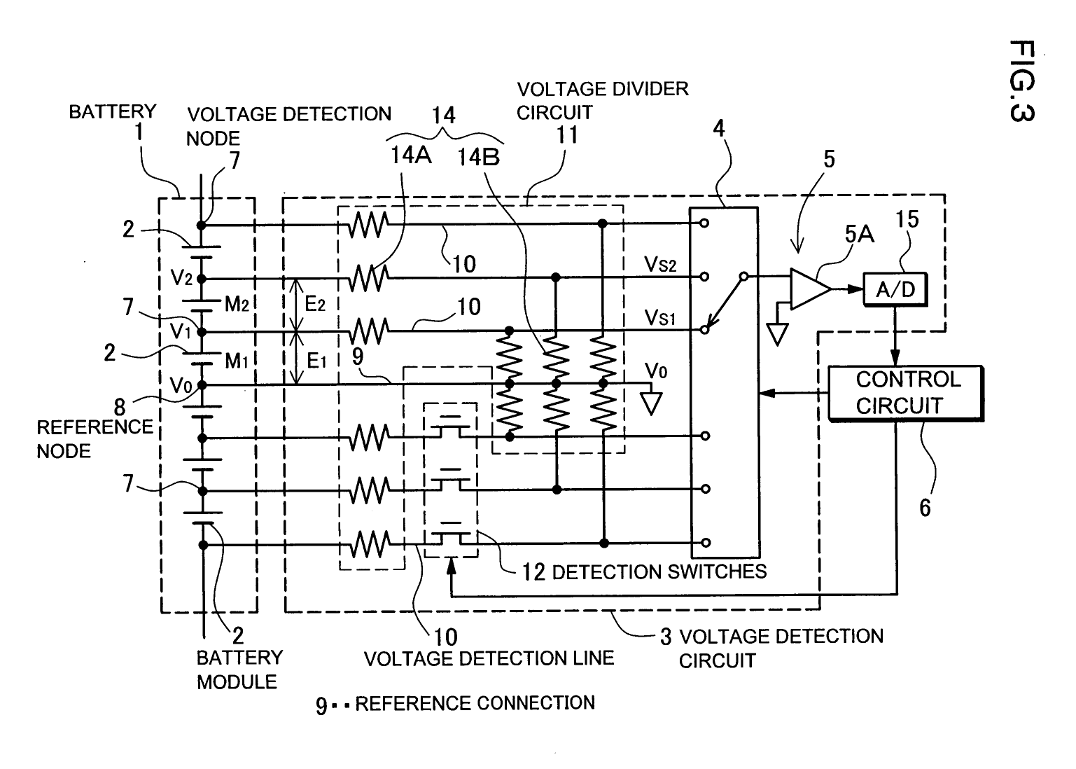

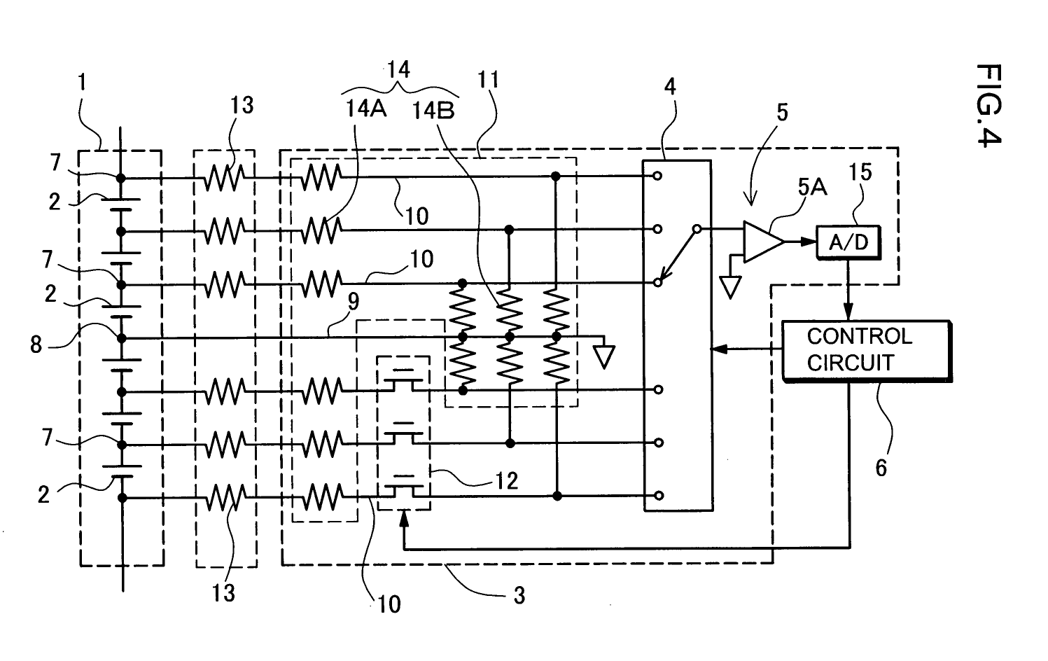

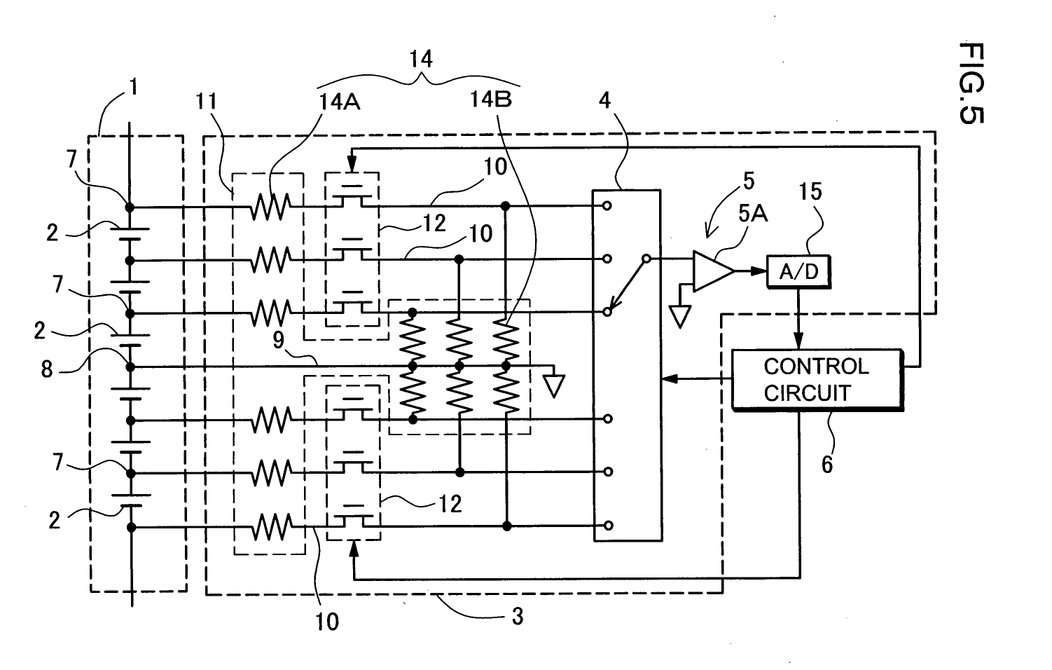

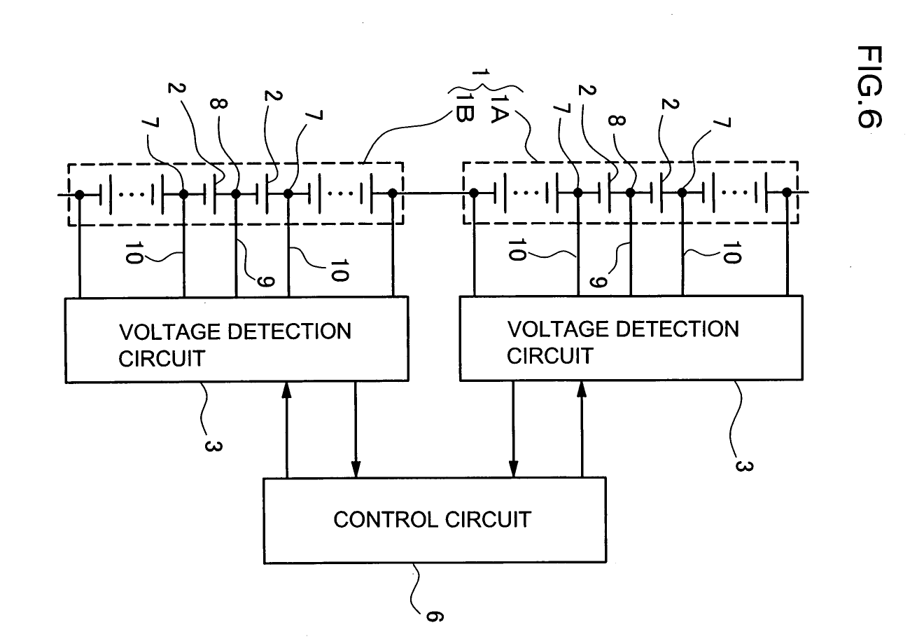

The car power source apparatus shown in FIGS. 3-6 are provided with driving batteries 1, 41, 51, 61 having a plurality of battery modules 2, 42, 52, 62 connected in series, and voltage detection circuits 3, 43, 53, 63 to detect the voltages of the battery modules 2, 42, 52, 62 that make up the driving batteries 1, 41, 51, 61. FIG. 3 shows the first embodiment, FIG. 4 shows the second embodiment, FIG. 5 shows the third embodiment, and FIG. 6 shows a power source apparatus combining the batteries and voltage detection circuits of FIGS. 3-5.

The voltage detection circuits 3, 43, 53, 63 of FIGS. 3-6 detect the voltage of each battery module 2, 42, 52, 62. Consequently, in this power source apparatus, the connection node of each battery module 2, 42, 52, 62 is connected to a voltage detection circuit 3, 43, 53, 63 as a voltage detection node 7, 47, 57, 67. Thus, voltage detection nodes 7, 47, 57, 67 are connection nodes for the voltage detection circuit 3, 43, 53, 63 to measure voltage. Although not illustrated, a voltage detection circuit can also treat a plurality of battery modules 2, 42, 52, 62 as a unit and detect the voltage of those single units. For example, in a battery that is a series connection of 50 battery modules, it is desirable for the voltage detection circuit to independently detect the voltage of each of the 50 battery modules. However, two battery modules can also be treated as a single unit and the total voltage of two battery modules can be detected instead.

The detected battery module 2, 42, 52, 62 voltages are used to determine remaining capacity of those battery modules 2, 42, 52, 62, to correct the remaining capacity computed by integrating charging and discharging current, to cut-off discharge current in an over-discharge state when remaining capacity becomes zero and complete discharge has been detected, or to cut-off charging current in an over-charge state when full charge has been detected.

The battery modules 2, 42, 52, 62 of a series connected driving battery 1, 41, 51, 61 are charged and discharged with the same current. Therefore, the charging capacity and discharging capacity of all the battery modules 2, 42, 52, 62 is the same. However, electrical characteristics of all the battery modules 2, 42, 52, 62 do not necessarily change together uniformly. In particular, as the number of charge-discharge cycles increases, the degree of degradation of each battery module 2, 42, 52, 62 becomes different, and the capacity at full charge varies. In this situation, battery modules 2, 42, 52, 62 with reduced full charge capacity are easily over-charged and over-discharged. Since battery module electrical characteristics markedly degrade with over-charge and over-discharge, a battery module with reduced full charge capacity degrades abruptly when over-charged or over-discharged. Consequently, for a driving battery 1, 41, 51, 61 having many battery modules 2, 42, 52, 62 connected in series, it is important to charge and discharge while protecting those battery modules 2, 42, 52, 62. Namely, it is important to charge and discharge while preventing over-charge and over-discharge of all battery modules 2, 42, 52, 62. To charge and discharge while protecting all battery modules 2, 42, 52, 62, a voltage detection circuit 3, 43, 53, 63 detects the voltage of each battery module 2, 42, 52, 62.

The power source apparatus of FIG. 6 divides the entire battery 61 into two blocks. Two sets of voltage detection circuits 63 are provided to detect the voltage of this battery 61, which is divided into two blocks. For example, a driving battery 61, which has a total of 50 battery modules 62 connected in series, can be divided into a first block 61A of 25 battery modules and a second block 61 B of 25 battery modules, or it can be divided into two blocks with different numbers of battery modules that total 50, such as a first block of 24 battery modules and a second block of 26 battery modules.

Each battery module 2, 42, 52, 62 has five nickel hydrogen batteries connected in series. Altogether the driving battery 1, 41, 51, 61 has 250 nickel hydrogen batteries connected in series for an output voltage of 300V. However, a battery module 2 does not necessarily have five batteries connected in series, and it may have four rechargeable batteries or less, or six rechargeable batteries or more connected in series. In addition, a driving battery does not necessarily have 50 battery modules connected in series, and it may have a fewer number of battery modules or a greater number of battery modules connected in series. Further, other types of rechargeable batteries, such as lithium ion rechargeable batteries or nickel cadmium batteries may also be used as the rechargeable batteries of the battery modules.

In a power source apparatus that connects 50 battery modules 62 in series and detects voltage with two voltage detection circuits 63, as shown in FIG. 6, one voltage detection circuit 63 detects the voltage of 24 to 26 battery modules 62.

The driving batteries shown in FIGS. 3-6 have a plurality of battery modules 2, 42, 52, 62 connected in series on the positive and negative sides of a reference node 8, 48, 58, 68 near the midpoint potential. Although the reference node 8, 48, 58 shown in FIGS. 3-5 is at the midpoint potential, the reference node can be near the midpoint potential when many battery modules are connected. The voltage detection circuit 3, 43, 53, 63 detects voltages at voltage detection nodes 7, 47, 57, 67 with respect to the reference node 8, 48, 58, 68 of the battery 1, 41, 51, 61, and the voltage of each battery module 2, 42, 52, 62 is computed from the difference in voltage detection node 7, 47, 57, 67 voltages. The battery 1, 41, 51, 61 reference node 8, 48, 58, 68 is connected to a voltage detection circuit 3, 43, 53, 63 via a reference connection line 9, 49, 59, 69. The reference connection line 9, 49, 59, 69 connects to the battery 1, 41, 51, 61 reference node 8, 48, 58, 68 at one end via a terminal or connector, and the other end it is a lead that connects to the voltage detection circuit 3, 43, 53, 63. This reference connection line 9, 49, 59, 69 becomes the ground line of the voltage detection circuit 3, 43, 53, 63. However, the reference connection line 9, 49, 59, 69, which becomes the voltage detection circuit 3, 43, 53, 63 ground line is not connected to the automobile chassis ground. This is to prevent electric shock.

Voltage detection nodes 7, 47, 57, 67, which are connection nodes of the battery modules 2, 42, 52, 62, are connected to a voltage detection circuit 3, 43, 53, 63 via voltage detection lines 10, 410, 510, 610. A voltage detection circuit 3, 43, 53, 63 detects voltages at the voltage detection nodes 7, 47, 57, 67 to determine the voltage of each battery module 2, 42, 52, 62.

As shown in FIGS. 3-5, the voltage detection circuit 3, 43, 53 is provided with resistor voltage divider circuitry 11, 411, 511 to divide the voltage at each voltage detection node 7, 47, 57, which is the connection node of each battery module 2, 42, 52; detection switches 12, 412, 512 connected in the voltage detection lines 10, 410, 510; a multiplexer 4, 44, 54 to switch resistor divided voltages by time division multiplexing for detection by the voltage detection circuit 3, 43, 53, 63; and a voltage detection section 5, 45, 55 connected to the output side of the multiplexer 4, 44, 54. Further, the power source apparatus shown in FIG. 4 has a short circuit current limiting resistor 413 connected in each voltage detection line 410. Short circuit current limiting resistors 413 prevent large short circuit currents from flowing if a voltage detection line 410 short circuit occurs. Short circuit current limiting resistor 413 electrical resistance is large at several tens of KΩ to limit short circuit current to a small value.

Each voltage divider circuit 11, 411, 511 has two resistors 14, 414, 514 connected in series to divide the voltage at the voltage detection node 7, 47, 57 for input to the multiplexer 4, 44, 54. This is because the highest voltage detection node 7, 47, 57 voltage is higher than the maximum multiplexer 4, 44, 54 input voltage. The voltage divider circuit 11, 411, 511 drops detection node 7, 47, 57 voltage by a set voltage divider ratio. The voltage divider ratio of the voltage divider circuit 11, 411, 511 is set by the electrical resistance of the two series connected resistors 14, 414, 514. By increasing the electrical resistance of the parallel resistor 14B, 414B, 514B, which is connected in parallel with the multiplexer 4, 44, 54 input, compared to the series resistor 14A, 414A, 514A, voltage division by the voltage divider circuit 11, 411, 511 can be increased. Namely, multiplexer 4, 44, 54 input voltage can be reduced.

The power source apparatus of FIG. 4 has short circuit current limiting resistors 413 connected in series with voltage divider circuitry 411. Although not illustrated, short circuit current limiting resistors 413 are fixed to an end-plate that is attached to the battery case. In this power source apparatus, the electrical resistance of the series resistor 414A of a voltage divider circuit 411 is set considering the resistance of the short circuit current limiting resistor 413. Specifically, the electrical resistance of the series resistor 414A is made a value that subtracts the resistance of the short circuit current limiting resistor 413. In this power source apparatus, the series resistor 414A of a voltage divider circuit 411 connects to a voltage detection node 47 via a short circuit current limiting resistor 413.

It is desirable for a voltage divider circuit 11, 411, 511 to drop the voltage at a voltage detection node 7, 47, 57 by several volts for input to the multiplexer 4, 44, 54. The ratio by which the voltage divider circuit 11, 411, 511 reduces detection node 7, 47, 57 voltage is set by the resistor ratio. Therefore, as described later, the detected voltage is input to the control circuit 6, 46, 56 via the voltage detection section 5, 45, 55 and an analog-to-digital (A/D) converter 15, 415, 515, where the actual detection node 7, 47, 57 voltage is computed with corrections made considering the resistor ratio of the voltage divider circuit 11, 411, 511. For example, if the resistor ratio (parallel/(series+parallel)) of the voltage divider circuit 11, 411, 511 is 1/50, the voltage detection circuit 3, 43, 53 multiplies the detected voltage by 50 to give the voltage of the voltage detection node 7, 47, 57.

A voltage divider circuit 11, 411, 511 is connected to each voltage detection node 7, 47, 57. Specifically, voltage at all detection nodes 7, 47, 57 is reduced by voltage divider circuitry 11, 411, 511 and input to the multiplexer 4, 44, 54. The resistor divider ratio of the voltage divider circuit 11, 411, 511 connected to each voltage detection node 7, 47, 57 is set to make the voltage input to the multiplexer 4, 44, 54 approximately equal for all voltage detection nodes 7, 47, 57.

Detection switches 12, 412, 512 are connected in voltage detection lines 10, 410, 510. Detection switches 12, 412, 512 are connected at intermediate locations along the voltage detection lines 10, 410, 510. Detection switches 12, 412, 512 are switched OFF when detecting reference connection line 9, 49, 59 open circuit, and are switched ON when the voltage detection circuit 3, 43, 53 is detecting the voltage of each battery module 2, 42, 52. Reference connection line 9, 49, 59 open circuit detection takes place immediately after the ignition switch is turned on. Consequently, detection switches 12, 412, 512 are controlled to temporarily switch OFF immediately after the ignition switch is turned on.

In the power source apparatus of FIGS. 3 and 4, detection switches 12, 412 are connected at intermediate locations along voltage detection lines 10, 410 connected to negative side battery module 2, 42 voltage detection nodes 7, 47. In the power source apparatus of FIG. 5, detection switches 512 are connected to voltage detection lines 510 of battery modules 52 on both the positive and negative sides of the reference node 58. In a power source apparatus with detection switches 512 connected in all voltage detection lines 510 as shown in FIG. 5, all detection switches 512 can be switched OFF to cut-off battery 51 discharge current through voltage divider circuitry 511 when the car is not in use. Therefore, in this power source apparatus, detection switches 512 serve a dual purpose as current cut-off switches. From a different perspective, current cut-off switches, which suspend battery 51 discharge when the ignition switch is in the off state, serve a dual purpose as detection switches 512.

As shown in FIGS. 3 and 4, reference connection line 9, 49 open circuit can be detected with connection of detection switches 12, 412 only in voltage detection lines 10, 410 on the negative side of the reference node 8, 48. However, as shown in FIG. 5, reference connection line 59 open circuit can also be detected with detection switches 512 connected to voltage detection lines 510 on both the positive and negative sides. Further, although not illustrated, reference connection line open circuit can also be detected with detection switches connected only in voltage detection lines on the positive side of the reference node.

Detection switches 12, 412, 512 are controlled ON and OFF by the control circuit 6, 46, 56. The control circuit 6, 46, 56 turns the detection switches 12, 412, 512 OFF for reference connection line 9, 49, 59 open circuit detection when the ignition switch is turned on, and it turns detection switches 12, 412, 512 ON when detecting battery module 2, 42, 52 voltage. In addition, when the ignition switch is switched to the off state, the control circuit 6, 46, 56 turns detection switches 12, 412, 512 OFF to cut-off battery 1, 41, 51 discharge current.

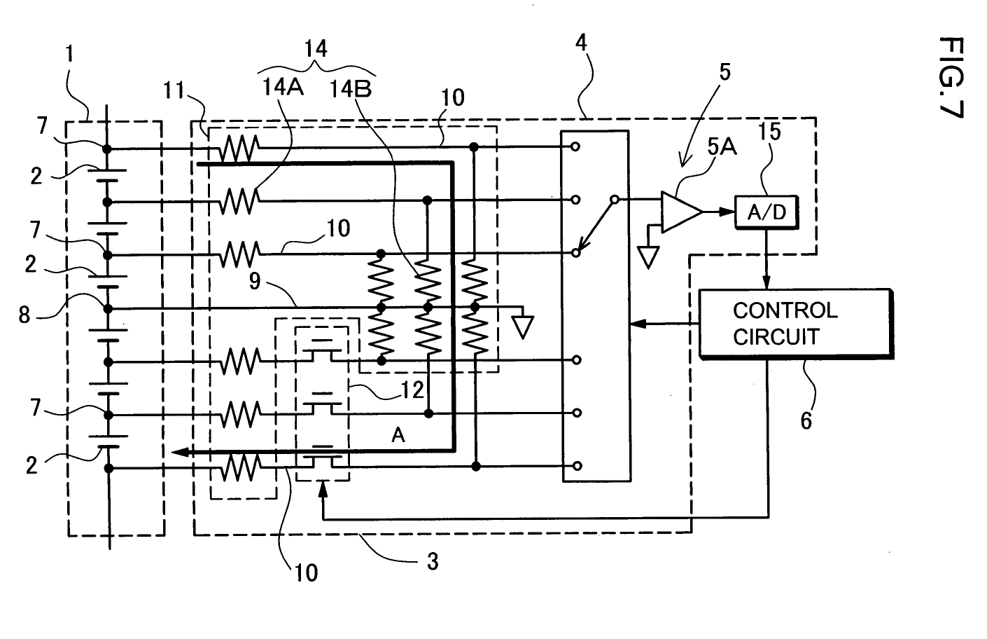

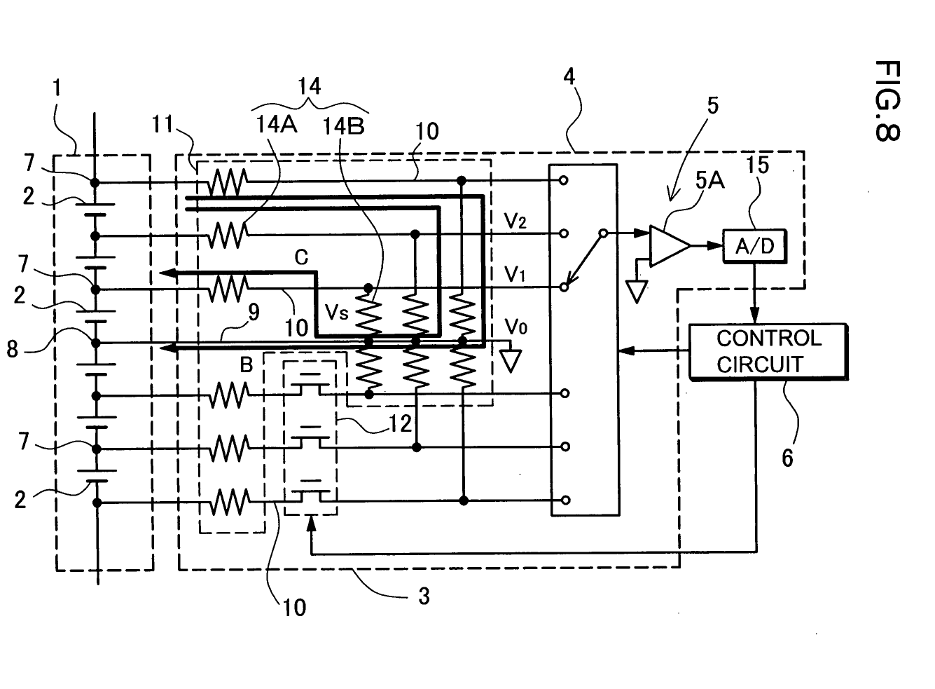

Operating principles to explain reference connection line open circuit detection with detection switches turned OFF are shown in FIGS. 7 and 8. However, these figures show operating principles for the power source apparatus of FIG. 3. If the reference connection line 9 is open circuited and detection switches 12 are ON, current flows through the path shown by arrow A in FIG. 7. In a prior art power source apparatus without ON-OFF control of detection switches, loop current indicated by the arrow would flow because no detection switches could be turned OFF. The loop current generates a voltage drop across a parallel resistor 14B. As a result, even with a reference connection line 9 open circuit, voltage input to the multiplexer 4 is not much different than the expected input voltage. Consequently, with the detection switches 12 in the ON state, reference connection line 9 open circuit cannot be discerned from A/D converter results.

As shown in FIG. 8, when negative side detection switches 12 are turned OFF, loop current ceases to flow in negative side voltage detection lines 10. If the reference connection line 9 is not open circuited, loop current flows as shown by arrow B. Specifically, the positive side voltage divider circuit 11 correctly divides detection node 7 voltage, which is input to the multiplexer 4. Therefore, the voltage detection circuit 3 correctly measures detection node 7 voltage. However, if the reference connection line 9 is open circuited, loop current does not flow through the reference connection line 9, but rather flows from high potential voltage detection nodes 7 to lower potential voltage detection nodes 7 as shown by arrow C. In FIG. 8, current flowing in the direction of arrow C flows in a reverse direction through parallel resistor 14B and series resistor 14A. This reverse current flow through parallel resistor 14B develops a negative voltage V1 at the multiplexer 4 input. Consequently, a negative voltage is detected for a positive side detection node 7 voltage. A positive side detection node 7 voltage cannot be negative with respect to the reference node 8. Therefore, when detection switches 12 are in the OFF state and the detected voltage of a positive side voltage detection node 7 is negative, the reference connection line 9 can be judged to have an open circuit. Further, if the reference connection line 9 is judged to have an open circuit, the power source apparatus is used in a mode that restricts battery 1 output.

In a power source apparatus with detection switches 12 connected in negative side voltage detection lines 10, reference connection line 9 open circuit is detected as described above. In a power source apparatus as shown in FIG. 5 with detection switches 512 connected in positive side voltage detection lines 510, the situation is opposite that described previously. When positive side detection switches 512 are in the OFF state and the detected voltage of a negative side voltage detection node 57 is positive, the reference connection line 59 is judged to have an open circuit.

As shown in FIGS. 3-5, the multiplexer 4, 44, 54 is connected on the input side of the voltage detection circuit 3, 43, 53, and it switches battery module 2, 42, 52 connection nodes to input the voltage at each voltage detection node 7, 47, 57 to the voltage detection section 5, 45, 55. The voltage detection circuit 3, 43, 53 multiplexer 4, 44, 54 switches the battery module 2, 42, 52 for voltage detection and successively outputs the voltage at all battery module 2, 42, 52 voltage detection nodes 7, 47, 57 to the voltage detection section 5, 45, 55. Consequently, the multiplexer 4, 44, 54 is connected at the input side of the voltage detection section 5, 45, 55, and it sequentially switches the battery module 2, 42, 52 connection node detected by the voltage detection section 5, 45, 55.

The voltage detection section 5, 45, 55 detects battery module 2, 42, 52 voltage by detecting the voltage at a battery module 2, 42, 52 voltage detection node 7, 47, 57 with respect to the reference node 8, 48, 58. The reference node 8, 48, 58 is an intermediate point between the plurality of series connected battery modules 2, 42, 52 with approximately an equal number of battery modules 2, 42, 52 connected on the positive and negative sides of the reference node 8, 48, 58. The voltage detection section 5, 45, 55 of the figures is a difference amplifier 5A, 45A, 55A. The difference amplifier 5A, 45A, 55A has one input terminal connected to the reference node 8, 48, 58 and the other input terminal connected through the multiplexer 4, 44, 54 to a battery module 2, 42, 52 connection node to detect detection node 7, 47, 57 voltage with respect to the reference node 8, 48, 58. However, the voltage detection section does not necessarily have to be a difference amplifier. This is because other amplifier configurations with the reference node connected to the negative side and a battery module connection node connected through the multiplexer to the positive side can also detect battery module connection node voltage with respect to the reference node.

Battery module 2, 42, 52 voltage is detected as the voltage difference between connection nodes connected to both terminals of a battery module 2, 42, 52. For example in FIG. 3, voltage E1 of battery module M1 is detected as V1−V0, and voltage E2 of battery module M2 is detected as V2−V1. Calculation of battery module 2, 42, 52 voltage from the difference between detection node 7, 47, 57 voltages is performed by the control circuit 6, 46, 56. In the voltage detection circuit 3, 43, 53 of the figure, the output side of the multiplexer 4, 44, 54 is connected to the voltage detection section 5, 45, 55, and the output side of the voltage detection section 5, 45, 55 is connected to the A/D converter 15, 415, 515. The voltage detection circuit 3, 43, 53 sequentially switches voltage detection nodes 7, 47, 57 via the multiplexer 4, 44, 54 to measure detection node 7, 47, 57 voltages via the voltage detection section 5, 45, 55, converts voltage detection section 5, 45, 55 output to a digital signal via the A/D converter 10, 410, 510, and inputs that digital signal to the control circuit 6, 46, 56. The control circuit 6, 46, 56 operates on the input digital voltage signal to determine battery module 2, 42, 52 voltage.

The voltage detection circuit 3, 43, 53 measures detection node 7, 47, 57 voltages with respect to the reference node 8, 48, 58 of the battery 1, 41, 51. Namely, the voltage detection circuit measures detection node 7, 47, 57 voltages with the reference node 8, 48, 58 voltage as a reference. Consequently, if the reference node 8, 48, 58 voltage is disrupted, none of the detection node 7, 47, 57 voltages can be accurately detected, and none of the battery module 2, 42, 52 voltages can be accurately determined as well. The reference node 8, 48, 58 of the battery 1, 41, 51 is connected to the voltage detection circuit 3, 43, 53 via the reference connection line 9, 49, 59. The reference connection line 9, 49, 59 connects the input side of the voltage detection circuit 3, 43, 53 to the reference node 8, 48, 58 of the battery 1, 41, 51 via a connection cord. Further, the connection cord connects to the reference node 8, 48, 58 of the battery 1, 41, 51 via a connector or terminal. The connection cord, which is connected at one end to the reference node 8, 48, 58, is connected at the other end by solder attach or via a connector to the input side of the voltage detection circuit 3, 43, 53, which is implemented by a printed circuit board with surface mounted electronic components. Contact resistance can easily occur at the connection cord, connector, or terminal. If contact resistance develops in the reference connection line 9, 49, 59, reference node 8, 48, 58 voltage, which is input to the voltage detection circuit 3, 43, 53, will vary. As contact resistance increases to a high value, it is ultimately judged as an open circuit.

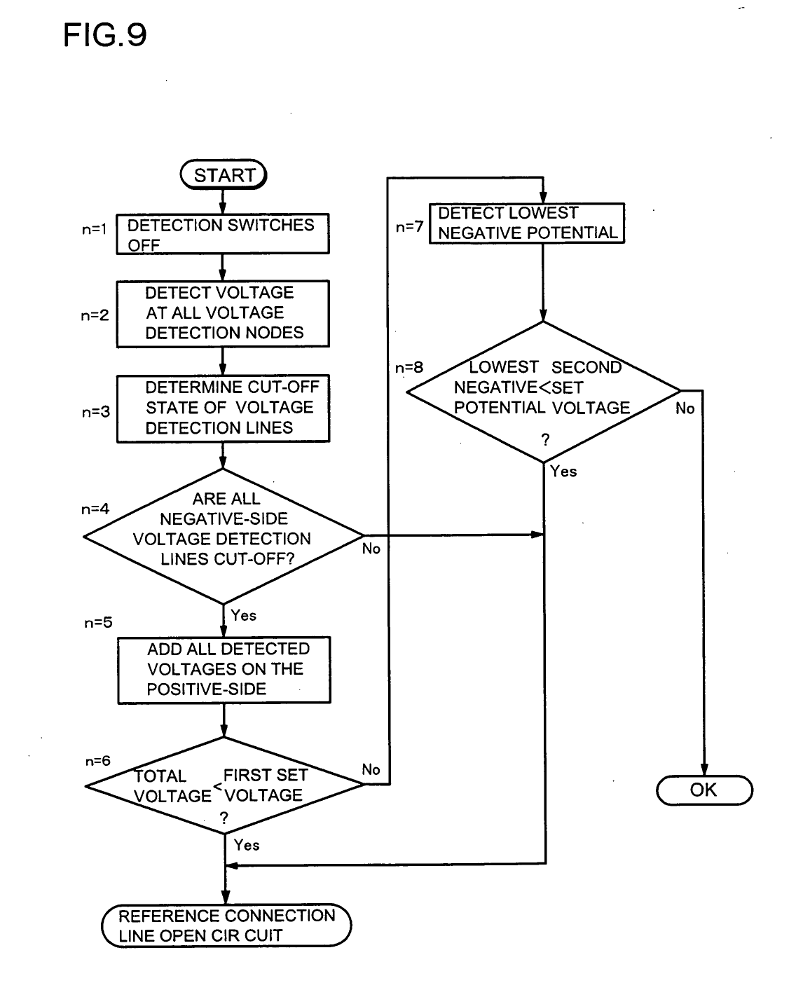

FIG. 9 shows a flow-chart for power source apparatus detection of reference connection line 9 open circuit. This flow-chart shows the steps for detecting reference connection line 9 open circuit in the power source apparatus of FIG. 3. This flow-chart shows reference connection line 9 open circuit detection by the following steps, which are steps that do not affect voltage detection during normal system operation, or are steps according to commands from a main control circuit abbreviated in the drawings.

[Step n=1]

Turn detection switches 12 OFF.

[Step n=2]

Detect the voltage at all voltage detection nodes 7 by switching through the multiplexer 4.

[Steps n=3 and n=4]

Determine the cut-off state of negative side voltage detection lines 10. The cut-off state of negative side voltage detection lines 10 is determined by whether the detected voltage is zero volts or not. This is because the detected voltage should be zero volts if the voltage detection line 10 is cut-off. When the detection switches 12 are in the OFF state, all negative side voltage detection lines 10 must be at zero volts. If a voltage other zero is detected anywhere on the negative side, detection switch 12 control circuit failure is assumed, and this is judged the same as circuit failure (reference connection line open circuit). Of course, circuit failure by individual circuit can also be output.

[Steps n=5 and n=6]

If all negative side voltage detection lines 10 are cut-off, all positive side detected voltages are added to determine a total voltage. Since some detected voltage will be a negative potential if the reference connection line 9 is open circuited, the total voltage will be lower than a first set voltage. Consequently, if the total voltage is lower than the first set voltage, the reference connection line 9 is judged to have an open circuit.

[Steps n=7 and n=8]

If the total voltage is not lower than the first set voltage, the voltage detection line with the lowest detected negative potential is searched for, and that lowest negative potential is compared to a second set voltage. If the lowest negative potential is lower than the second set voltage, the reference connection line 9 is judged to have an open circuit. If the lowest negative potential is not lower than the second set voltage, the reference connection line 9 is judged to have no open circuit (and is O.K).

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within the meets and bounds of the claims or equivalence of such meets and bounds thereof are therefore intended to be embraced by the claims. This application is based on Application No. 2005-99,312 filed in Japan on Mar. 30, 2005, the content of which is incorporated hereinto by reference.

What is claimed is:

1. A car power source apparatus comprising:
a battery having a plurality of battery modules connected in series on the positive and negative sides of a reference node, and
a voltage detection circuit for detecting the voltage of one or a plurality of battery modules with respect to the reference node of the battery;
wherein the reference node of the battery is connected to the voltage detection circuit via a reference connection line, voltage detection nodes of the battery are connected to the voltage detection circuit via voltage detection lines, and voltage detection node voltages are detected by the voltage detection circuit to determine battery module voltages; and
wherein the voltage detection circuit has detection switches connected in voltage detection lines, the voltage detection circuit detects voltage detection node voltages with the detection switches in the OFF state, and reference connection line open circuit is detected from those detected voltages.

2. A car power source apparatus as recited in claim 1 wherein a voltage detection line is connected to the connection node of each battery module, and the voltage detection circuit detects the voltage of each battery module.

3. A car power source apparatus as recited in claim 1 wherein battery module voltage detected by the voltage detection circuit is used to detect battery module remaining capacity.

4. A car power source apparatus as recited in claim 1 wherein all battery modules are divided into two blocks, and two voltage detection circuits are provided to detect the voltage of each battery module in the two blocks.

5. A car power source apparatus as recited in claim 1 wherein a battery module has a plurality of rechargeable batteries connected in series, and those rechargeable batteries can be either nickel hydrogen batteries, lithium ion rechargeable batteries, or nickel cadmium batteries.

6. A car power source apparatus as recited in claim 1 wherein the voltage detection circuit detects the voltage of voltage detection nodes with respect to the reference node of the battery, and computes the voltage of each battery module from the difference between detected voltage detection node voltages.

7. A car power source apparatus as recited in claim 1 wherein the reference connection line is a lead that connects via a terminal and connector to the reference node of the battery at one end, and to the voltage detection circuit at the other end.

8. A car power source apparatus as recited in claim 1 wherein the reference connection line is the ground line of the voltage detection circuit.

9. A car power source apparatus as recited in claim 7 wherein the reference connection line of the voltage detection circuit is a ground line that is not connected to the car chassis ground.

10. A car power source apparatus as recited in claim 1 wherein the voltage detection circuit is provided with a multiplexer to detect voltage by time division multiplexing, and the voltage of a plurality of battery modules are detected by switching the multiplexer via time division multiplexing.

11. A car power source apparatus as recited in claim 1 wherein the voltage detection circuit is provided with resistor voltage divider circuitry, and voltage input from a voltage detection line is detected after being divided by a resistor voltage divider circuit.

12. A car power source apparatus as recited in claim 11 wherein the voltage detection circuit is provided with resistor voltage divider circuitry and a multiplexer to switch via time division multiplexing and detect voltages divided by the resistor voltage divider circuitry; and the voltage divider ratios of the resistor voltage divider circuitry are set to make all voltages input to the multiplexer approximately equal.

13. A car power source apparatus as recited in claim 1 wherein detection switches are connected at intermediate locations along voltage detection lines; the detection switches are switched OFF when reference connection line open circuit is being detected, and are switched ON when the voltage of each battery module is being detected by the voltage detection circuit.

14. A car power source apparatus as recited in claim 1 wherein detection switches are connected to voltage detection nodes of battery modules on both the positive and negative sides.

15. A car power source apparatus as recited in claim 1 wherein detection switches connected in all voltage detection lines serve a dual purpose as current cut-off switches to cut-off battery discharge current.

16. A car power source apparatus as recited in claim 1 wherein the reference node is the midpoint of the plurality of series connected battery modules, and approximately the number of battery modules are connected on the positive and negative sides of the reference node.

17. A car power source apparatus as recited in claim 15 wherein some of the detection switches are switched OFF to detect reference connection line open circuit.

18. A car power source apparatus as recited in claim 1 wherein current limiting resistors are connected in all voltage detection lines.
